(19) United States
(12) Patent Application Publication
(10) Pub. No.: US 2019/0218656 A1
(43) Pub. Date: Jul. 18, 2019

(54) EVAPORATION SOURCE DEVICE AND EVAPORATOR

(71) Applicant: Wuhan China Star Optoelectronics Semiconductor Display Technology Co., Ltd., Wuhan, Hubei (CN)

(72) Inventor: Junying MU, Wuhan, Hubei (CN)

(21) Appl. No.: 15/578,091

(22) PCT Filed: Aug. 21, 2017
(86) PCT No.: PCT/CN2017/098339

§ 371 Date: Nov. 29, 2017

(30) Foreign Application Priority Data
Jul. 28, 2017 (CN) 201710633446.1

(51) Int. Cl. C23C 14/24; C23C 14/12

(52) U.S. Cl. CPC C23C 14/24; H01L 51/001; C23C 14/12

(57) ABSTRACT

An evaporation source device is provided. The evaporation source device includes a first container, a second container at position in the first container for accommodating and heating organic materials, and a blocking element at position outside the first container. The nozzles and fumaroles respectively are positioned on a top of the first container and a top of the second container, the blocking element located around a nozzle bore of the nozzle, and the nozzle bore has inverted trapezoidal cross-section. An evaporator is further provided. The cross-section of the nozzle bore is inverted trapezoidal, and position blocking element on periphery of the nozzle bore for blocking or limiting deposition of the unused direction spraying organic materials. Also improving depositing on inner surface of blocking element, increased utilization ratio of the evaporation material and avoided nozzle blocked.

### RELATED APPLICATIONS

The present application is a National Phase of International Application Number PCT/CN2017/098339, filed Aug. 21, 2017, and claims the priority of China Application No. 201710633446.1, filed Jul. 28, 2017.

### BACKGROUND OF THE INVENTION

### 1. Field of the Invention

The disclosure relates to a manufacture of organic light-emitting display technical field, and more particularly to an evaporation source device and an evaporator.

### 2. The Related Arts

Comparing to the OLED (Organic Light-Emitting Diode) displays technology and the mainstream LCD (Liquid crystal display) technology, the OLED display have numerous advantages such as high contrast, wider color gamut, flexible, thin bodies, energy saving, radiation-free, etc. Current mainstream OLED technology has gradually arisen, and universal applied to mobile devices for example smart phone, panel, or flexible wearable devices for example smart watch, large size curved television, white light illumination.

Major technology of OLED includes a small molecule OLED technology based on vacuum evaporator and a polymer OLED technology based on solution process. Evaporator is a major apparatus of produce the currently mass production of small molecule OLED element. The core part of the evaporator is evaporation source device.

In commonly evaporation source device, there will mounting restriction plate around nozzle of evaporation source cavity for controlling evaporating angle and avoiding evaporating gas be deposited on the non-substrate region which is upper evaporator source device. However, organic gas sprayed from nozzle is axiolite-shaped so that most of material will be deposited on the restriction plate caused low utilization of the organic evaporation material. Also there will get risk of pilling materials when organic material is accumulated to a certainly thickness on the inner wall of the restriction plate. Finally, the nozzle will be blocked and effect continuous operation time of evaporator cause to huge economic losses.

### SUMMARY

A technical problem to be solved by the disclosure is to provide an evaporation source device and an evaporator with increased utilization ratio of the evaporation material and avoided nozzle blocked.

An objective of the disclosure is achieved by following embodiments. In particular, an evaporation source device includes a first container, a second container and a blocking element. The second container is at position in the first container for accommodating and heating organic materials. Nozzles and fumaroles are respectively positioned on a top of the first container and a top of the second container. The blocking element is located around a nozzle bore of the nozzle. The cross-section of the nozzle bore is inverted trapezoidal.

In an embodiment, periphery of the nozzle bore comprises an annular auxiliary heating source for heating an inner wall of the nozzle bore.

In an embodiment, the nozzle bore is cylindrical or prism.

In an embodiment, the blocking element comprises a first blocking element and a second blocking element opposite positioned to the first blocking element, and the first blocking element and the second blocking element are respectively arranged on two sides of the nozzle.

In an embodiment, the evaporation source device has multiple nozzle bores and the nozzles are strip-shaped, all the nozzle bores are positioned on the nozzles.

In an embodiment, the evaporation source device has multiple nozzle bores linearly distributed on the top of the first container, and the first blocking element and the second blocking element are respectively located on two sides of the multiple nozzle bores.

In an embodiment, the evaporation source device has multiple nozzle bores arranged in rows on the top of the first container, the extending direction of the first blocking element and the second blocking element are parallel to arrangement direction of each row of the nozzle bores, and the first blocking element and the second blocking element are respectively located on two sides of the rows of the nozzle bores.

In an embodiment, the blocking element further comprises a third blocking element positioned between the first blocking element and the second blocking element, and the third blocking element is position between two adjacent rows of the nozzle bores.

In an embodiment, two inclined surfaces of the third blocking element are respectively toward to two adjacent rows of the nozzle bores.

According to another aspect of the disclosure, the disclosure further provides an evaporator. The evaporator includes an evaporation source device as described above.

The cross-section of the nozzle bore is inverted trapezoidal in this disclosure, and position blocking element on periphery of the nozzle bore for blocking or limiting deposition of the unused direction spraying organic materials. Also improving depositing on inner surface of blocking element, increased utilization ratio of the evaporation material and avoided nozzle blocked.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a structural schematic view of an evaporator according to the first embodiment of the disclosure;

FIG. 2 is a length direction cross sectional schematic view of an evaporation source device according to the first embodiment of the disclosure;

FIG. 3 is a width direction cross sectional schematic view of the evaporation source device according to the first embodiment of the disclosure;

FIG. 4a is a top view of the evaporation source device according to the first embodiment of the disclosure;

FIG. 4b is a top view of the another evaporation source device according to the first embodiment of the disclosure;

FIG. 5 is a partial structural schematic view of the evaporation source device according to the first embodiment of the disclosure; and

FIG. 6 is a top view of the evaporation source device according to the second embodiment of the disclosure.

### DETAILED DESCRIPTION OF THE PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

### Embodiment 1

The disclosure will be further described in detail with reference to accompanying drawings and preferred embodiments as follows.

Please refer to FIG. 1. The evaporator major comprises an evaporation source device 1. The evaporation source device 1 can spray organic material toward to the surface of substrate which on the evaporation source device, and forming a particular pattern organic film F on surface of substrate 2 by a shield plate has pattern thereon.

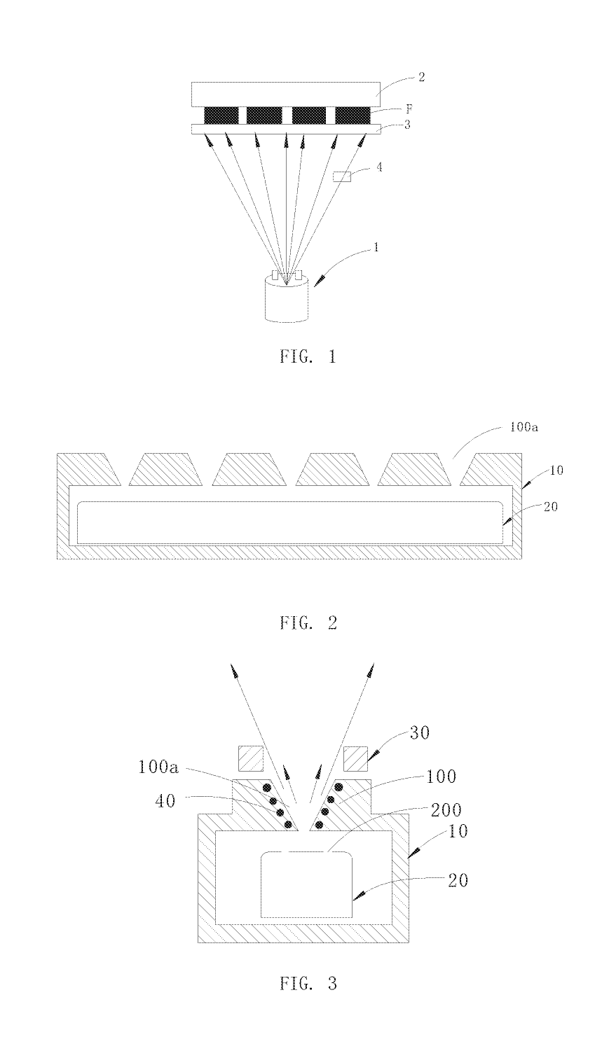

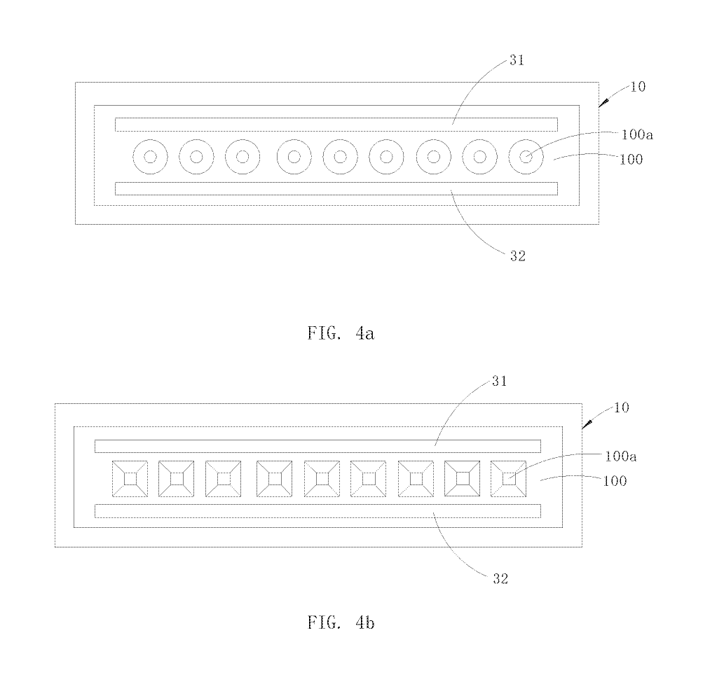

Please refer to FIG. 2 and FIG. 3. The evaporation source device 1 of this embodiment comprises a first container 10, a second container 20 and blocking element 30. The second container 20 is positioned in the first container 10 for accommodating and heating organic materials. The blocking element 30 is positioned outside the first container 10. The nozzles 100 and fumaroles 200 are respectively positioned on a top of the first container 10 and a top of the second container 20, the blocking element 30 is located around a nozzle bore 100a of the nozzle 100, and cross-section of the nozzle bore 100a is inverted trapezoidal. A flow rate monitor 4 is positioned on the first container 10 for detecting real time spray speed of organic material.

The blocking element 30 comprises a first blocking element 31 and a second blocking element 32 is opposite positioned to the first blocking element 31. The nozzle 100 is strip-shaped. There are forming a linearly distributing nozzle bores 100a on the top of nozzles 100. The first blocking element 31 and the second blocking element 32 are respectively located on two sides of the linearly distributing nozzle bores 100a. The nozzle bores are cylindrical (shown as FIG. 4a), or the nozzle bores are prism (shown as FIG. 4b) so that inner wall of the nozzle bores is open-shaped. Because of the first container 10 is vacuum, the organic material are sprayed approximate straight-line from the fumaroles 200 and the nozzle 100 in sequentially while the organic materials be heated to vaporization in the second container 20. Moreover, the spraying direction is limited by special shaped of the nozzle 100 so that the organic material spayed by unused direction will be blocked or limited and the organic material only could be deposited on the correspondingly region of the upper substrate 2 along the nozzle 100 defined direction. The surface of the nozzle bores 100a only have less organic material be deposited such that enhancing the material utilization.

In this embodiment, the first blocking element 31 and the second blocking element 32 both are strip-shaped. Both of the length of the first blocking element 31 and the second blocking element 32 are greater or equal to the arrangement length of the nozzle bores 100a. Therefore, limited the spraying direction of all nozzle bores 100a.

In addition, in this embodiment, periphery of the nozzle bore 100a comprises an annular auxiliary heating source 40 heating for an inner wall of the nozzle bore 100a. Please refer to FIG. 3. The auxiliary heating source 40 is positioned in the nozzle 100. Specifically, the auxiliary heating source 40 is positioned nearby the surface of nozzle bore 100a. There also could disposes a cooling device (not shown) on periphery of nozzle 100. Heating the nozzle 100 by control auxiliary heating source 40 during evaporation process, which could prevents organic material deposited in the nozzle bores 100a so that avoid the nozzle blocked. Also, cooling down the nozzle 100 by cooling device while overheating, which could ensures continuously evaporation.

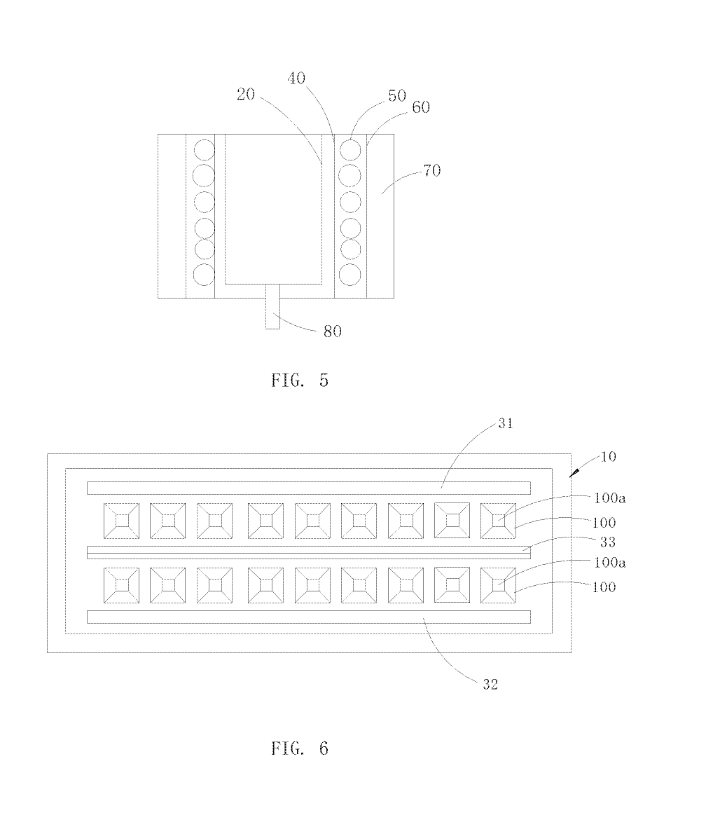

Please refer to FIG. 5. The evaporation source device 1 of this embodiment comprises a second container 20, a heat insulation layer 40, a heating source 50, a heat reflection layer 60, a POW (Plant Cooling Water/Process Cooling Water) 70 and a temperature sensor 80 are arranged in sequence from inside to outside. The second container 20 is a crucible. The heat insulation layer 40 is positioned between the heating source 50 and the second container 20. The heating source 50 is heating the organic material of the second container 20 by induction heating. The heat reflection layer 60 is positioned around the heating source 50 for reducing the heat loss. The PCW as a dissipating heat system and cooling down the evaporation source device. The temperature sensor 80 is disposed on bottom of the second container 20 for detecting temperature of the second container 20, and controlling the heating temperature according to the real time spray speed of organic material by the flow rate monitor 4. Therefore, it can be achieved uniform coating.

### Embodiment 2

Please refer to FIG. 6. In this embodiment which is different to the embodiment 1. In this embodiment, the multiple nozzle bores 100a are arranged in rows on the top of the first container 10. The extending direction of the first blocking element 31 and the second blocking element 32 are parallel to arrangement direction of each row of the nozzle bores 100a, and the first blocking element 31 and the second blocking element 32 are respectively located on two sides of the rows of the nozzle bores 100a.

In addition, the blocking element 30 further comprises a third blocking element 33. The third blocking element 33 is positioned between the first blocking element 31 and the second blocking element 32, and the third blocking element 33 is position between two adjacent rows of the nozzle bores 100a. In order to limited spray direction of two adjacent rows of the nozzle bores 100a on width direction of the evaporation source device. The inclined surfaces of the third blocking element 33 are respectively toward to two adjacent rows of the nozzle bores 100a such that cross section of the third blocking element 33 is triangle to form wedge structure.

The cross-section of the nozzle bore of present invention is trapezoidal cross-section, and positioning blocking element for blocking or limiting unused direction of the spraying organic materials be deposited, and controlling the temperature of inner wall of the nozzle bore. It is improving the organic material depositing on inner surface of blocking element, and increasing utilization ratio of the evaporation material and avoided nozzle blocked.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A evaporation source device, comprising
a first container;
a second container at position in the first container for accommodating and heating organic materials; and
a blocking element at position outside the first container;
wherein nozzles and fumaroles are respectively positioned on a top of the first container and a top of the second container, the blocking element located around a nozzle bore of the nozzle, and cross-section of the nozzle bore is inverted trapezoidal.

2. The evaporation source device according to claim 1, wherein periphery of the nozzle bore comprises an annular auxiliary heating source for heating an inner wall of the nozzle bore.

3. The evaporation source device according to claim 1, wherein the nozzle bore is cylindrical or prism.

4. The evaporation source device according to claim 1, wherein the blocking element comprises a first blocking element and a second blocking element opposite positioned to the first blocking element, and the first blocking element and the second blocking element are respectively arranged on two sides of the nozzle.

5. The evaporation source device according to claim 4, wherein the evaporation source device has multiple nozzle bores and the nozzles are strip-shaped, all the nozzle bores are positioned on the nozzles.

6. The evaporation source device according to claim 4; wherein the evaporation source device has multiple nozzle bores linearly distributed on the top of the first container, and the first blocking element and the second blocking element are respectively located on two sides of the multiple nozzle bores.

7. The evaporation source device according to claim 4, wherein the evaporation source device has multiple nozzle bores arranged in rows on the top of the first container, the extending direction of the first blocking element and the second blocking element are parallel to arrangement direction of each row of the nozzle bores, and the first blocking element and the second blocking element are respectively located on two sides of the rows of nozzle bores.

8. The evaporation source device according to claim 7, wherein the blocking element further comprises a third blocking element positioned between the first blocking element and the second blocking element, and the third blocking element is positioned between two adjacent rows of the nozzle bores.

9. The evaporation source device according to claim 8, wherein two inclined surfaces of the third blocking element are respectively toward to two adjacent rows of the nozzle bores.

10. The evaporation source device according to claim 2, wherein the blocking element comprises a first blocking element and a second blocking element opposite position to the first blocking element, and the first blocking element and the second blocking element are respectively arranged on two sides of the nozzle.

11. A evaporator, comprises an evaporation source device, the evaporation source device, comprising
a first container;
a second container at position in the first container for accommodating and heating organic materials; and
a blocking element at position on the first container;
wherein nozzles and fumaroles are respectively positioned on a top of the first container and a top of the second container, the blocking element located around a nozzle bore of the nozzle, and cross-section of the nozzle bore is inverted trapezoidal.

12. The evaporator according to claim 11, wherein periphery of the nozzle bore comprises an annular auxiliary heating source for heating an inner wall of the nozzle bore.

13. The evaporator according to claim 11, wherein the nozzle bore is cylindrical or prism.

14. The evaporator according to claim 11, wherein the blocking element comprises a first blocking element and a second blocking element opposite positioned to the first blocking element, and the first blocking element and the second blocking element are respectively arranged on two sides of the nozzle.

15. The evaporator according to claim 14, wherein the evaporation source device has multiple nozzle bores and the nozzles are strip-shaped, all the nozzle bores are positioned on the nozzles.

16. The evaporator according to claim 14, wherein the evaporation source device has multiple nozzle bores linearly distributed on the top of the first container, and the first blocking element and the second blocking element are respectively located on two sides of the multiple nozzle bores.

17. The evaporator according to claim 14, wherein the evaporation source device has multiple nozzle bores arranged in rows on the top of the first container, the extending direction of the first blocking element and the second blocking element are parallel to arrangement direction of each row of the nozzle bores, and the first blocking element and the second blocking element are respectively located on two sides of the rows of the nozzle bores.

18. The evaporator according to claim 17 wherein the blocking element further comprises a third blocking element positioned between the first blocking element and the second blocking element, and the third blocking element is positioned between two adjacent rows of the nozzle bores.

19. The evaporator according to claim 18 wherein two inclined surfaces of the third blocking element are respectively toward to two adjacent rows of the nozzle bores.

20. The evaporator according to claim 12, wherein the blocking element comprises a first blocking element and a second blocking element opposite position to the first blocking element, and the first blocking element and the second blocking element are respectively arranged on two sides of the nozzle.
